(19) United States
(12) Patent Application Publication
(10) Pub. No.: US 2025/0142815 A1
(43) Pub. Date: May 1, 2025

(54) SEMICONDUCTOR DEVICE

(71) Applicant: UNITED MICROELECTRONICS CORP., Hsin-Chu City (TW)

(72) Inventors: Chang-Yih Chen, Tainan City (TW); Kuo-Hsing Lee, Hsinchu County (TW); Chun-Hsien Lin, Tainan City (TW); Wen-Chieh Chang, Hsinchu City (TW); Kun-Szu Tseng, Tainan City (TW); Sheng-Yuan Hsueh, Tainan City (TW); Yao-Jhan Wang, Tainan City (TW)

(73) Assignee: UNITED MICROELECTRONICS CORP., Hsin-Chu City (TW)

(21) Appl. No.: 18/519,092

(22) Filed: Nov. 27, 2023

(30) Foreign Application Priority Data
Oct. 27, 2023 (TW) 112141194

(51) Int. Cl. H10B 20/25

(52) U.S. Cl. CPC H10B 20/25

(57) ABSTRACT

A semiconductor device includes a substrate having a medium-voltage (MV) region and an one time programmable (OTP) capacitor region, a MV device on the MV region, and an OTP capacitor on the OTP capacitor region. Preferably, the MV device includes a first gate dielectric layer on the substrate, a first gate electrode on the first gate dielectric layer, and a shallow trench isolation (STI) adjacent to two sides of the first gate electrode. The OTP capacitor includes a fin-shaped structure on the substrate, a doped region in the fin-shaped structure, a second gate dielectric layer on the doped region, and a second gate electrode on the second gate dielectric layer.

### BACKGROUND OF THE INVENTION

### 1. Field of the Invention

The invention relates to a semiconductor device, and more particularly to a semiconductor device of integrating a medium-voltage (MV) device and an one-time programmable (OTP) device.

### 2. Description of the Prior Art

Semiconductor memory devices including non-volatile memory devices have been widely used in various electronic devices such as cellular phones, digital cameras, personal digital assistants (PDAs), and other applications. Typically, non-volatile memory devices include multi-time programmable (MTP) memory devices and one-time programmable (OTP) memory devices. In contrast to rewritable memories, OTP memory devices have the advantage of low fabrication cost and easy storage. However, OTP memory devices could only perform a single data recording action such that when certain memory cells of a destined storage block were stored with a writing program, those memory cells could not be written again.

Since current OTP memory devices still have the disadvantage of weak reading current and longer stress time under program mode, how to improve the current architecture for OTP memory devices has become an important task in this field.

### SUMMARY OF THE INVENTION

A semiconductor device includes a substrate having a medium-voltage (MV) region and an one time programmable (OTP) capacitor region, a MV device on the MV region, and an OTP capacitor on the OTP capacitor region. Preferably, the MV device includes a first gate dielectric layer on the substrate, a first gate electrode on the first gate dielectric layer, and a shallow trench isolation (STI) adjacent to two sides of the first gate electrode. The OTP capacitor includes a fin-shaped structure on the substrate, a doped region in the fin-shaped structure, a second gate dielectric layer on the doped region, and a second gate electrode on the second gate dielectric layer.

According to another aspect of the present invention, a semiconductor device includes a substrate having a medium-voltage (MV) region, an one time programmable (OTP) capacitor region, and a core region, a MV device on the MV region, an OTP capacitor on the OTP capacitor region, and a metal-oxide-semiconductor (MOS) transistor on the core region.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-11 illustrate a method for fabricating a semiconductor device according to an embodiment of the present invention.

FIG. 12 illustrates an overall layout of the semiconductor device according to an embodiment of the present invention.

### DETAILED DESCRIPTION

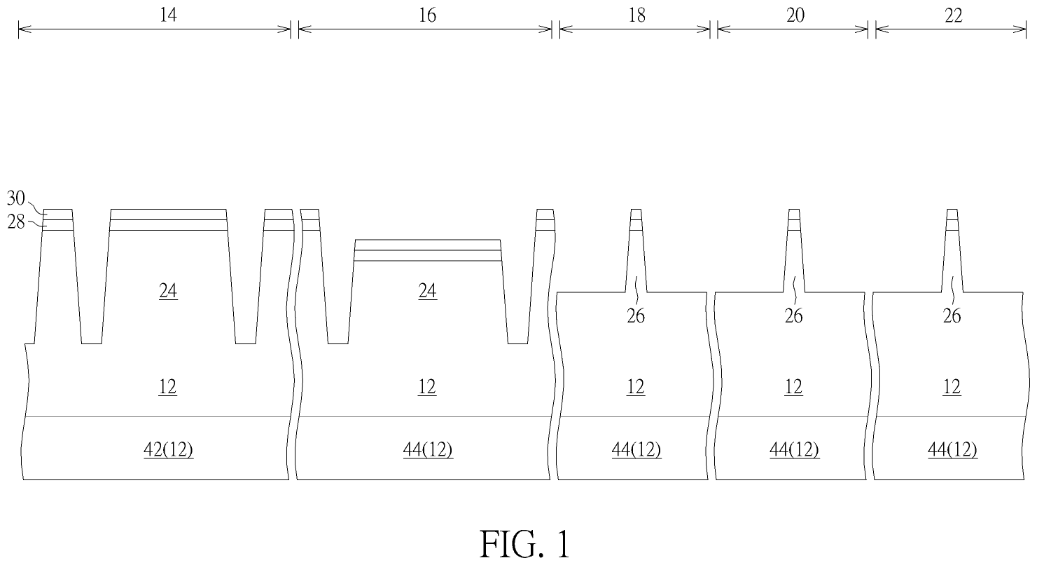

Referring to FIGS. 1-11, FIGS. 1-11 illustrate a method for fabricating a semiconductor device according to an embodiment of the present invention. As shown in FIG. 1, a substrate 12 such as a silicon substrate or silicon-on-insulator (SOI) substrate is provided and a high-voltage (HV) region 14, a medium-voltage (MV) region 16, an input/output (I/O) region 18, a core region 20, and an OTP capacitor region 22 are defined on the substrate 12, in which the HV region 14 and MV region 16 are used to fabricate HV devices and MV devices having planar type metal-oxide semiconductor field effect transistors (MOSFETs), the I/O region 18 and the core region 20 are used to fabricate low-voltage (LV) devices such as non-planar fin field effect transistors (FinFETs), and the OTP capacitor region 22 is used to fabricate OTP capacitors.

In this embodiment, the HV region 14, the MV region 16, the I/O region 18, the core region 20, and the OTP capacitor region 22 could include transistor regions having same or different conductive type. For instance, each of the HV region 14, the MV region 16, the I/O region 18, the core region 20, and the OTP capacitor region 22 could include a PMOS region and/or a NMOS region, and the five regions could be predetermined to fabricate gate structures having same or different threshold voltage in the later process. In this embodiment, it would be desirable to first conduct an ion implantation process to form a deep p-well 42 on the HV region 14 and then form deep a n-well 44 on the MV region 16, the I/O region 18, the core region 20, and the OTP capacitor region 22. Nevertheless, the conductive type of the deep wells on each region could all be adjusted according to the demand of the process.

Next, bases 24 are formed on substrate 12 of the HV region 14 and the MV region 16 and a plurality of fin-shaped structures 26 are formed on the substrate 12 of the I/O region 18, the core region 20, and the OTP capacitor region 22. Preferably, the fin-shaped structures 26 could be obtained by a sidewall image transfer (SIT) process. For instance, a layout pattern is first input into a computer system and is modified through suitable calculation. The modified layout is then defined in a mask and further transferred to a layer of sacrificial layer on a substrate through a photolithographic and an etching process. In this way, several sacrificial layers distributed with a same spacing and of a same width are formed on a substrate. Each of the sacrificial layers may be stripe-shaped. Subsequently, a deposition process and an etching process are carried out such that spacers are formed on the sidewalls of the patterned sacrificial layers. In a next step, sacrificial layers can be removed completely by performing an etching process. Through the etching process, the pattern defined by the spacers can be transferred into the substrate underneath, and through additional fin cut processes, desirable pattern structures, such as stripe patterned fin-shaped structures could be obtained.

Alternatively, the fin-shaped structures 26 could also be obtained by first forming a patterned mask (not shown) on the substrate, 12, and through an etching process, the pattern of the patterned mask is transferred to the substrate 12 to form the fin-shaped structures 26. Moreover, the formation of the fin-shaped structures 26 could also be accomplished by first forming a patterned hard mask (not shown) on the substrate 12, and a semiconductor layer composed of silicon germanium is grown from the substrate 12 through exposed patterned hard mask via selective epitaxial growth process to form the fin-shaped structures 26. These approaches for forming the fin-shaped structures 26 are all within the scope of the present invention.

In this embodiment, at least a liner 28 and a hard mask 30 could be disposed on the surface of the base 24 and fin-shaped structures 26 during the aforementioned patterning process, in which the liner 28 could include silicon oxide and/or silicon nitride while the hard mask 30 preferably includes silicon oxide. Moreover, it would be desirable to conduct an extra photo-etching process to remove part of the substrate 12 on the MV region 16 before forming the fin-shaped structures 26, and then forming the fin-shaped structures 26 thereafter. As a result, the top surface of the base 24 on the MV region 16 is slightly lower than the top surface of the base 24 and fin-shaped structures 26 on other regions.

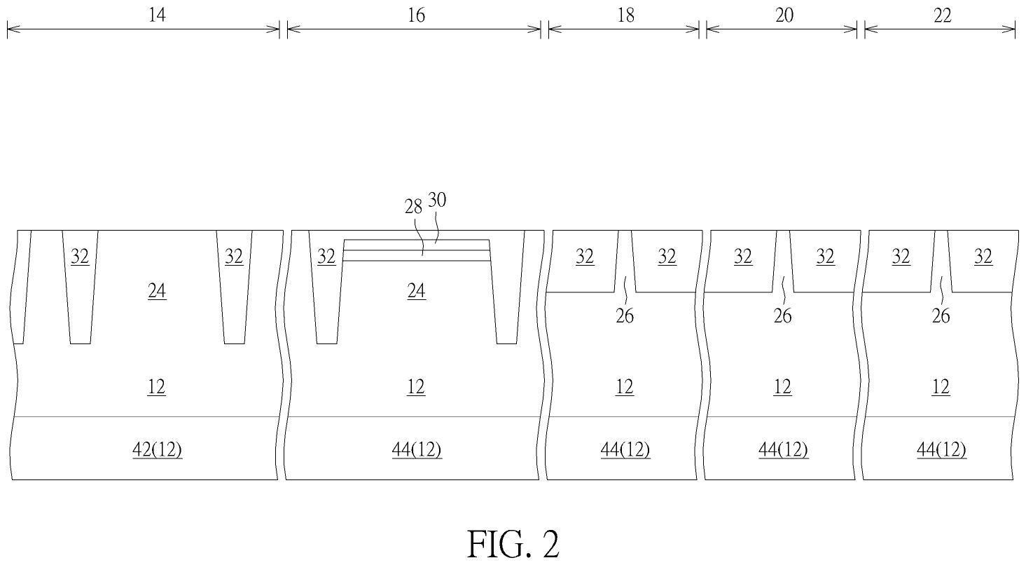

After the fin-shaped structures 26 are formed, another photo-etching process could be conducted to remove part of the substrate 12 on the HV region 14 and MV region 16 to form a plurality of deeper trenches (not shown). Next, as shown in FIG. 2, a flowable chemical vapor deposition (FCVD) process is conducted to form an insulating layer made of silicon oxide and fill the trenches, and a planarizing process such as chemical mechanical polishing (CMP) process is conducted to remove part of the insulating layer, part of the hard mask 30, and part of the liner 28 so that the top surface of the remaining the insulating layer is even with the top surface of the substrate 12 on each region and at the same time form deeper shallow trench isolation (STI) 32 on the HV region 14 and MV region 16 and shallower STI 32 on the I/O region 18, the core region 20, and the OTP capacitor region 22.

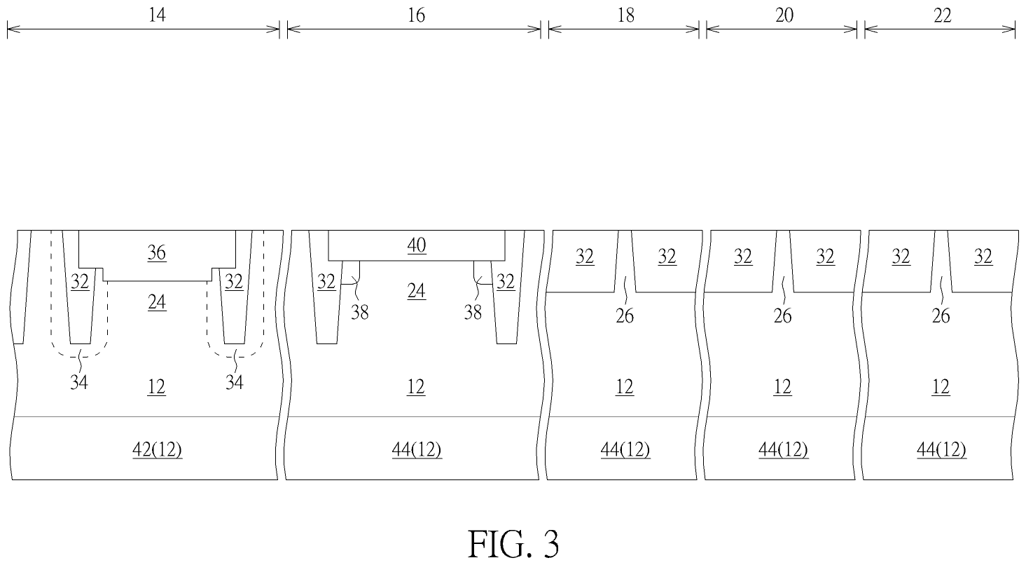

Next, as shown in FIG. 3, the remaining hard mask 30 and liner 28 on the MV region 16 are removed to expose the surface of the base 24, and then an ion implantation process is conducted to form a doped region 34 adjacent to two sides of the base 24 on the HV region 14, in which the doped region 34 could be serving as a lightly doped drain (LDD) 34 for the HV device in the later process. Next, an oxide growth process such as a rapid thermal oxidation (RTO) process could be conducted by using a mask to form a gate dielectric layer 36 made of silicon oxide on the base 24 of the HV region 14. Next, a LDD 38 is formed on the MV region 16, and another oxide growth process is conducted to form a gate dielectric layer 40 also made of silicon oxide on the base 24 of the MV region 16. It should be noted that as the hard mask 30 and liner 28 on the MV region 16 are removed, part of the STI 32 is also removed at the same time to form recesses so that the gate dielectric layer 40 formed afterwards is not only formed on the surface of the substrate 12 but also in the recess of the STI 32.

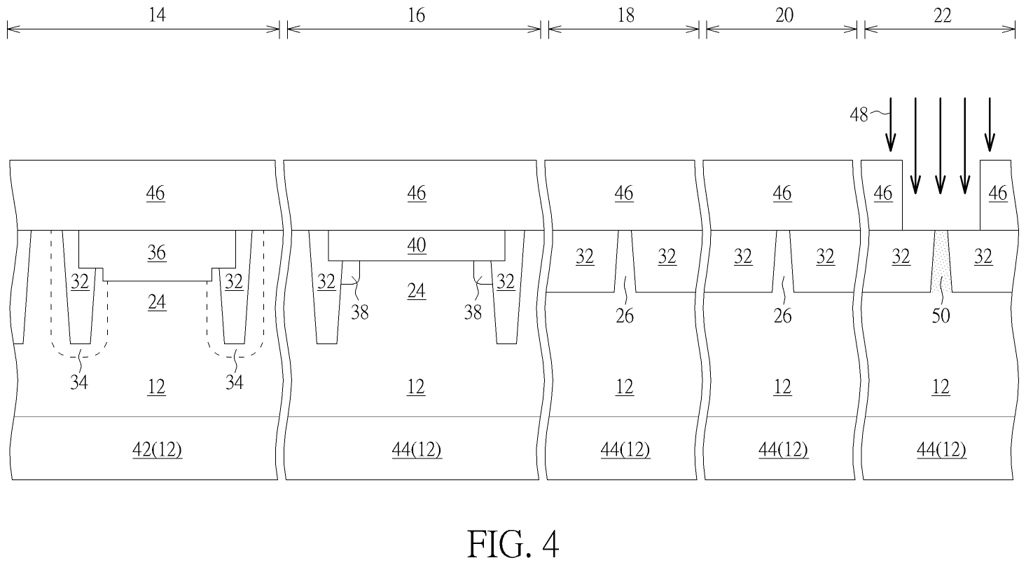

Next, as shown in FIG. 4, a patterned mask 46 such as a patterned resist is formed on the regions outside the OTP capacitor region 22 to expose the surface of the substrate 12 or fin-shaped structure 26 on the OTP capacitor region 22, and an ion implantation process 48 or a heavy doping process is conducted to implant dopants into the fin-shaped structure 26 on the OTP capacitor region 22 for forming a doped region 50. At this stage, the dopant concentrations of the substrate 12 on the HV region 14, MV region 16, I/O region 18, and core region 20 are all less than the dopant concentration of the fin-shaped structure 26 on the OTP capacitor region 22, in which the doped region 50 preferably serves as a bottom electrode for the OTP capacitor. In this embodiment, the implanted dopants for forming the doped region 50 preferably include arsenic (As), the energy of the ion implantation process is between 5-20 KeV, and the dosage of the dopants is between 1.0×10¹⁵ atoms/cm² to 1.0×10¹⁶ atoms/cm² and the concentration of dopants is approximately 1.0×10¹⁸ atoms/cm³ to 1.0×10²⁰ atoms/cm³.

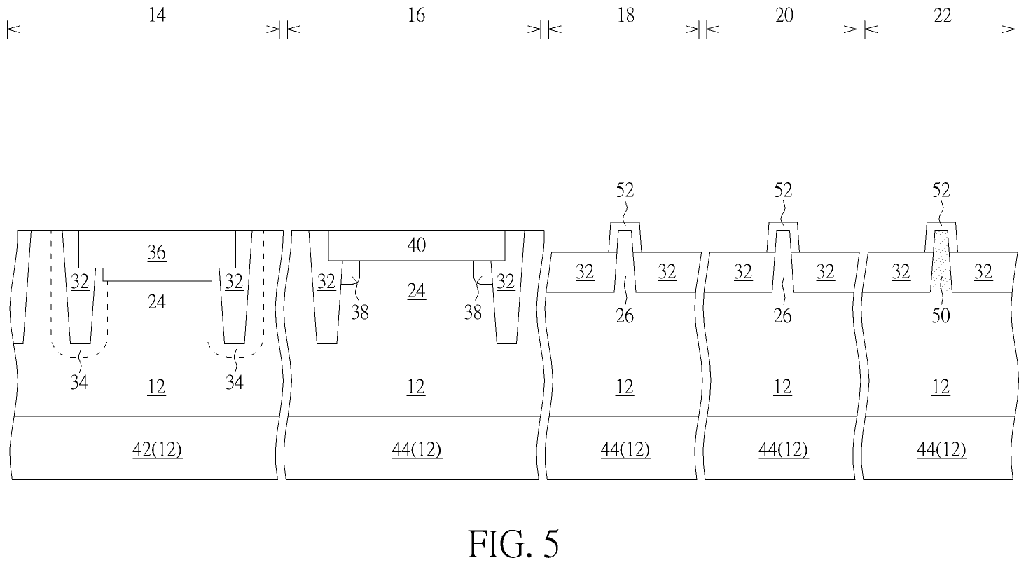

Next, as shown in FIG. 5, the patterned mask 46 could be removed and an anneal process is conducted to drive the implanted dopants into the fin-shaped structure 26 on the OTP capacitor region 22, a patterned mask (not shown) such as patterned resist is formed on the HV region 14 and MV region 16, an etching process is conducted to remove part of the STI 32 on the I/O region 18, the core region 20, and OTP capacitor region 22 so that the top surface of the STI 32 is slightly lower than the top surface of the fin-shaped structures 26. Next, an oxide growth process such as a RTO process or an in-situ steam generation (ISSG) process is conducted to form a gate dielectric layer 52 made of silicon oxide on the exposed fin-shaped structure 26 surface of each of the I/O region 18, core region 20, and OTP capacitor region 22.

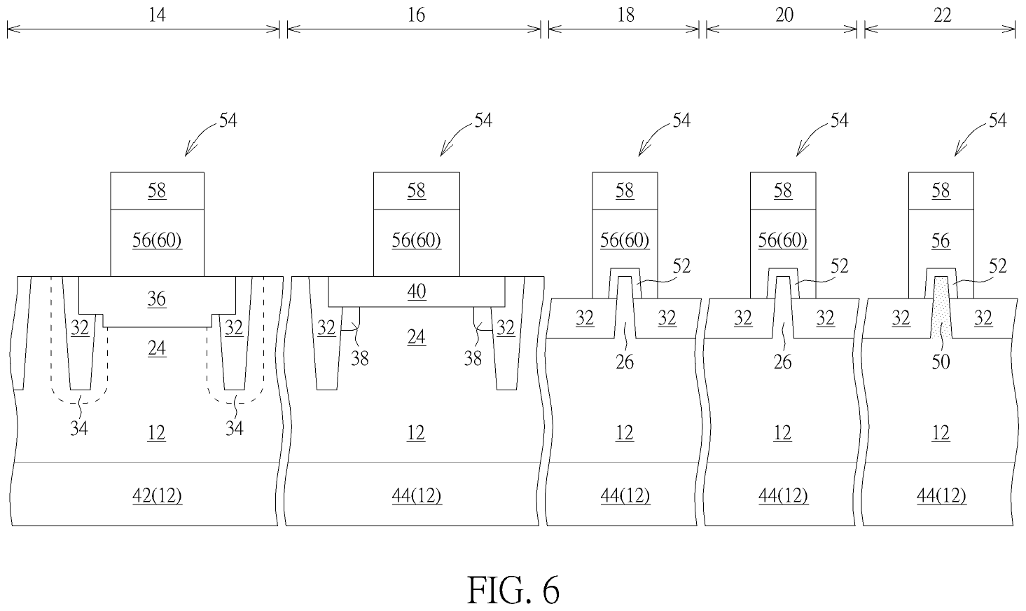

Next, as shown in FIG. 6, gate structures 54 could be formed on the bases 24 and fin-shaped structure 26 on the HV region 14, the MV region 16, the I/O region 18, the core region 20, and the OTP capacitor region 22, in which the gate structures 54 on the HV region 14, MV region 16, I/O region 18, and core region 20 could be serving as gate electrodes for each region while the gate structure 54 on the OTP capacitor region 22 could be serving as a top electrode for the OTP capacitor, and the formation of the gate structures 54 could be accomplished by a gate first process, a high-k first approach from gate last process, or a high-k last approach from gate last process.

Since this embodiment pertains to a high-k last approach, a gate material layer 56 made of polysilicon and a selective hard mask 58 could be formed sequentially on the substrate 12, and a photo-etching process is then conducted by using a patterned resist (not shown) as mask to remove part of the hard mask 58, part of the gate material layer 56, and part of the gate dielectric layer 52 through single or multiple etching processes. After stripping the patterned resist, gate structures 54 each made of a patterned material layer 56 and patterned hard mask 58 are formed on each of the regions, in which the patterned gate material layer 56 could be serving as gate electrodes 60 for the HV device, the MV device, the I/O device, and the core device and a top electrode for the OTP capacitor.

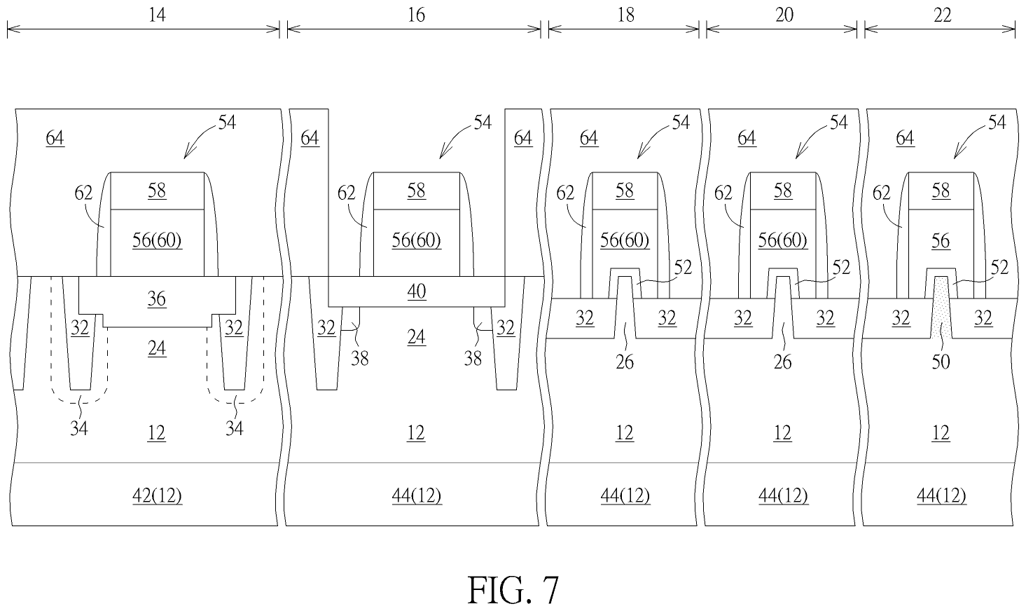

Next, as shown in FIG. 7, at least a spacer 62 is formed on the sidewalls of the each of the gate structures 54, and then a patterned mask 64 is formed on the HV region 14, I/O region 18, core region 20, and OTP capacitor region 22 to expose the gate dielectric layer 40 adjacent to two sides of the gate structure 54 on the MV region 16. In this embodiment, the spacer 62 could be a single spacer or a composite spacer, such as a spacer including but not limited to for example an offset spacer and a main spacer. Preferably, the offset spacer and the main spacer could include same material or different material while both the offset spacer and the main spacer could be made of material including but not limited to for example SiO₂, SiN, SiON, SiCN, or combination thereof.

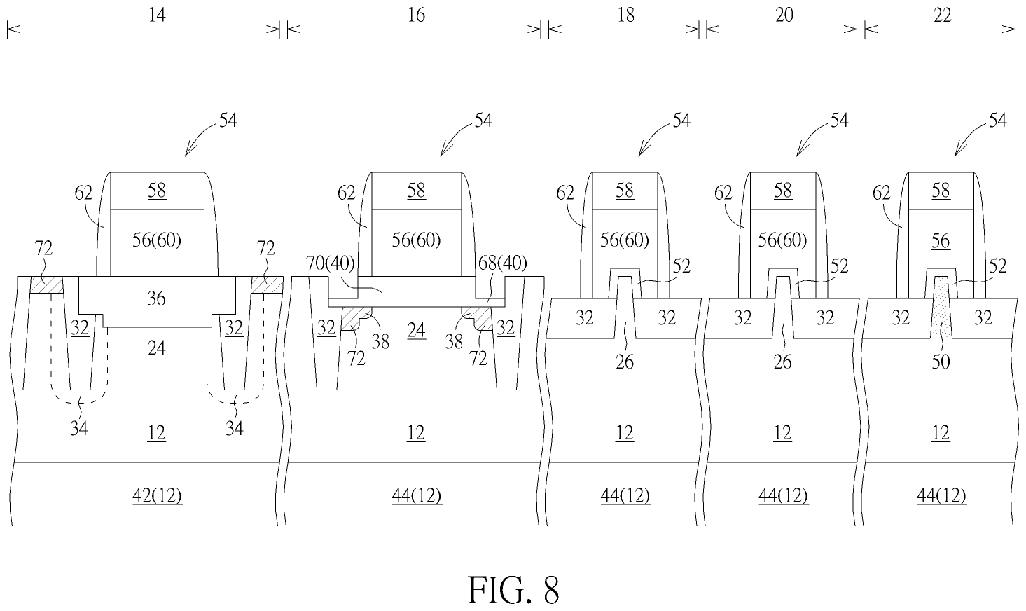

Next, as shown in FIG. 8, an etching process is conducted by using the patterned mask 64 as mask to remove part of the gate dielectric layer 40 adjacent to two sides of the gate structure 54 on the MV region 16 so that the remaining gate dielectric layer 40 forms a reverse T-shape. Specifically, the gate dielectric layer 40 modified by the etching process on the MV region 16 includes a bottom portion 68 disposed on the substrate 12 and STI 32 at the same time and a top portion 70 disposed on the bottom portion 68. Preferably, width of the top portion 70 is less than width of the bottom portion 68, the top surface of the top portion 70 could be even with the top surface of the fin-shaped structures 26 on the core region 20 and OTP capacitor region 22 and/or the top surface of the doped region 50 on the OTP capacitor region 22, sidewalls of the top portion 70 are aligned with sidewalls of the spacer 62, and the thickness of the bottom portion 68 is less than the thickness of the top portion 70. For instance, the thickness of the bottom portion 68 could be less than 90%, 80%, 70%, 60%, or 50% of the thickness of the top portion 70, the top surface of the bottom portion 68 is lower than the topmost surface of the STI 32 on the MV region 16 but could be higher than, even with, or lower than the top surface of the STI 32 on the I/O region 18, core region 20, and OTP capacitor region 22.

Next, source/drain regions 72 and/or epitaxial layers (not shown) are formed in the bases 24 or fin-shaped structures 26 adjacent to two sides of the spacers 62 on the HV region 14, MV region 16, I/O region 18, and core region 20, and selective silicide layers (not shown) could be formed on the surface of the source/drain regions 72 and/or epitaxial layers. The source/drain region 72 and the epitaxial layers could include different dopants or different materials depending on the type of device being fabricated. For instance, the source/drain region 72 could include n-type dopants or p-type dopants and the epitaxial layers could include silicon germanium (SiGe), silicon carbide (SiC), or silicon phosphide (SiP). It should be noted that since a capacitor is fabricated on the OTP capacitor region 2, the source/drain regions 72 are only formed in the substrate 12 adjacent to two sides of the gate structures 54 on the HV region 14, MV region 16, I/O region 18, and core region 20 while no source/drain region and/or epitaxial layer is formed in the fin-shaped structures 26 adjacent to two sides of the gate structure 54 (or top electrode) on the OTP capacitor region 22.

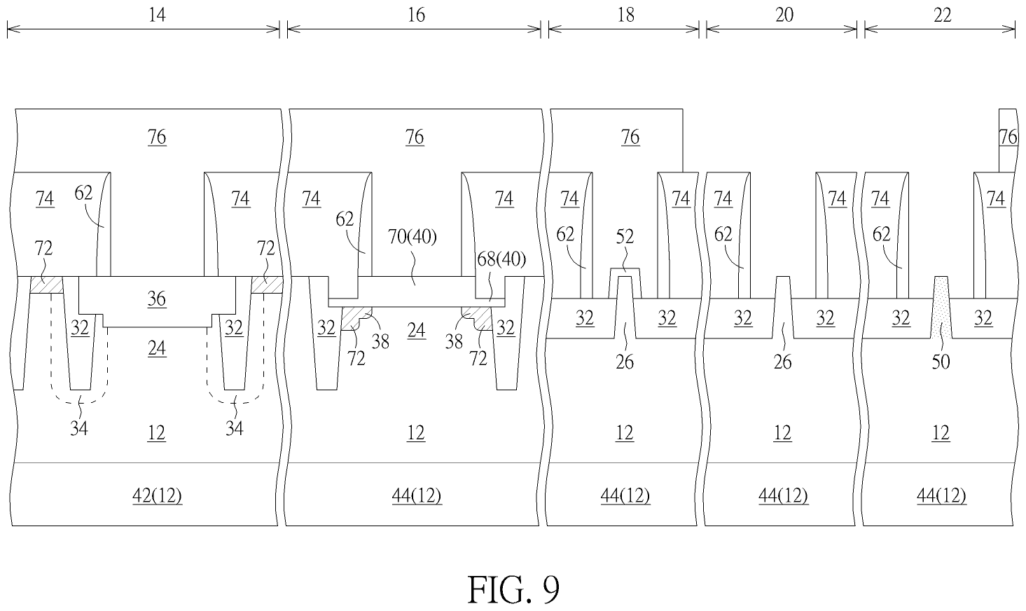

Next, as shown in FIG. 9, an interlayer dielectric (ILD) layer 74 is formed on the gate structures 54 and a planarizing process such as CMP is conducted to remove part of the ILD layer 74 for exposing the hard masks 58 so that the top surface of the hard masks 58 are even with the top surface of the ILD layer 76.

Next, a replacement metal gate (RMG) process is conducted to transform the gate material layers 56 made of polysilicon on the HV region 14, MV region 16, I/O region 18, core region 20, and OTP capacitor region 22 into metal gates. For instance, the RMG process could be accomplished by first performing a selective dry etching or wet etching process using etchants including but at not limited to for example ammonium hydroxide (NH₄OH) or tetramethylammonium hydroxide (TMAH) to remove the hard masks 58 and the gate material layers 56 on the HV region 14, MV region 16, I/O region 18, core region 20, and OTP capacitor region 22 for forming recesses exposing the gate dielectric layers 36, 40, 52 on each region.

Next, a patterned mask 76 such as patterned resist is formed on the HV region 14, the MV region 16, and I/O region 18 to expose the gate dielectric layers 52 on the core region 20 and OTP capacitor region 22, and then an etching process is conducted by using the patterned mask 76 as mask to remove the gate dielectric layers 52 on the core region 20 and OTP capacitor region 22 for exposing the surface of the fin-shaped structures 26.

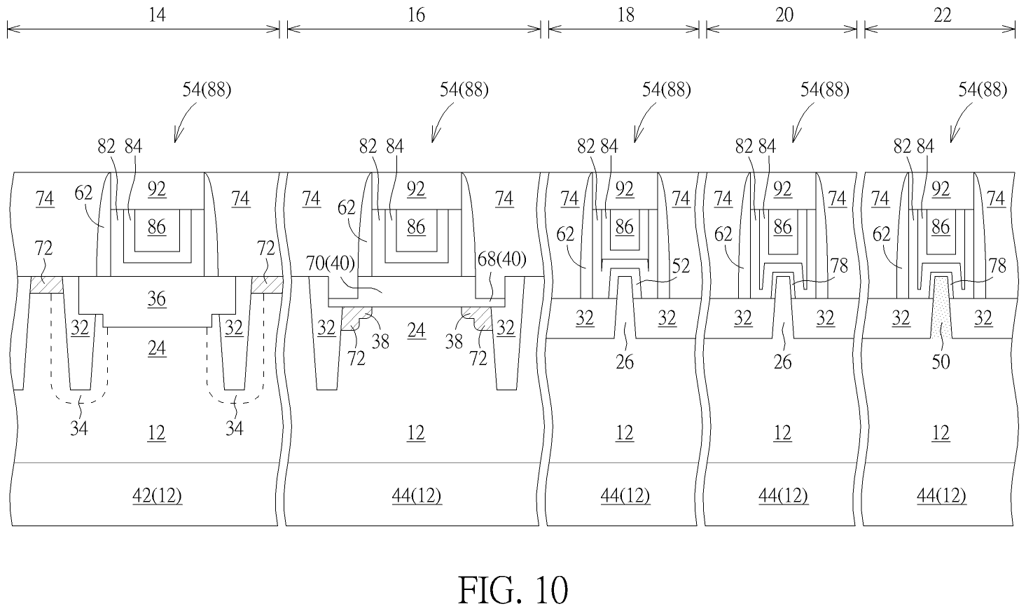

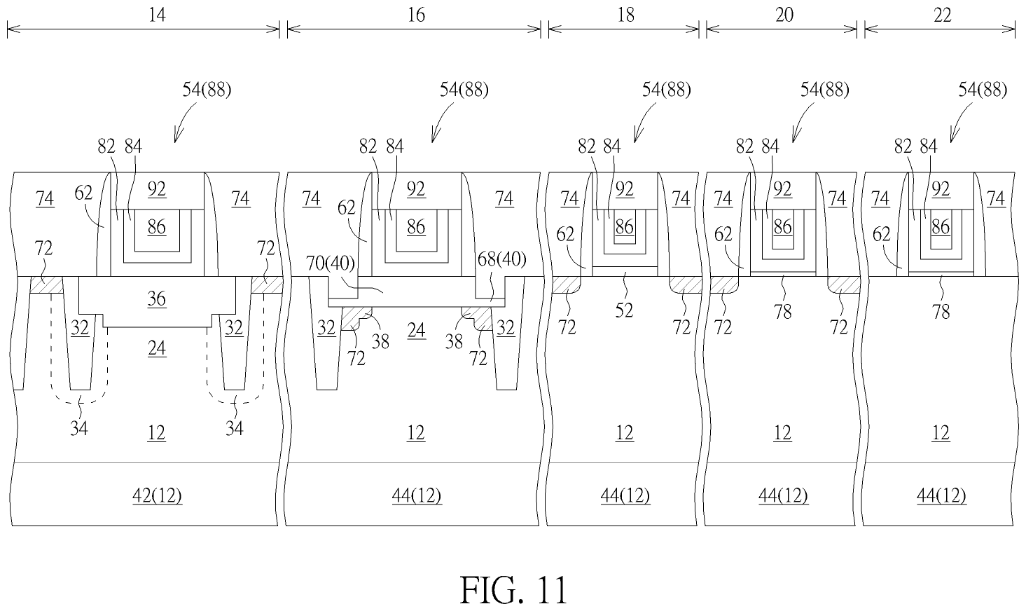

Next, referring to FIGS. 10-11, FIGS. 10-11 illustrate a method for fabricating metal gates on the HV region 14, MV region 16, I/O region 18, core region 20, and OTP capacitor region 22 following the RMG process conducted in FIG. 9, in which FIGS. 9-10 illustrate views under same cross-section on the HV region 14, MV region 16, I/O region 18, core region 20, and OTP capacitor region 22, the HV region 14 and MV region 16 of FIG. 11 are shown with same cross-section views as FIGS. 9-10, and the I/O region 18, the core region 20, and the OTP capacitor region 22 are cross-section views shown from a different angle. For instance, fin-shaped structures 26 are shown on the I/O region 18, core region 20, and OTP capacitor region 22 of FIG. 10 after RMG process whereas source/drain regions 72 are shown on the I/O region 18 and core region 20 of FIG. 11 as no source/drain region is shown on the OTP capacitor region 22.

As shown in FIGS. 10-11, an interfacial layer 78 made of silicon oxide layer is formed on the substrate 12 surface of the core region 20 and OTP capacitor region 22, the patterned mask 76 is removed, a high-k dielectric layer 82, a work function metal layer 84, and a low resistance metal layer 86 are formed in the recesses of each region, and then a planarizing process such as CMP is conducted to remove part of the low resistance metal layer 86, part of the work function metal layer 84, and part of the high-k dielectric layer 82 to form metal gates 88. Since this embodiment pertains to be a high-k last process, each of the metal gates 88 preferably includes a U-shape high-k dielectric layer 82, a U-shape work function metal layer 84, and a low resistance metal layer 86.

It should be noted that even though the interfacial layer 78 on the core region 20 and OTP capacitor region 22 and the gate dielectric layer 52 on the I/O region 18 are both made of silicon oxide, the thickness of the interfacial layer 78 is slightly less than the thickness of the gate dielectric layer 52 or more specifically the thickness of the interfacial layer 78 is less than half the thickness of the gate dielectric layer 52 on the I/O region 18. Moreover, instead of forming interfacial layers 78 having same thickness on the core region 20 and OTP capacitor region 22 as disclosed in this embodiment, according to other embodiment of the present invention, it would also be desirable to conduct an extra oxidation process for forming interfacial layers both made of silicon oxide but having different thicknesses on the core region 20 and OTP capacitor region 22 separately, in which the thickness of the interfacial layer on the OTP capacitor region 22 in such instance would be less than the thickness of the interfacial layer on the core region 20 while the thickness of the interfacial layer on the core region 20 would be less than the thickness of the gate dielectric layer 52 on the I/O region 18. In this instance, the interfacial layers and gate dielectric layers on the I/O region 18, core region 20, and OTP capacitor region 22 would then have three different thicknesses, which is also within the scope of the present invention.

In this embodiment, the high-k dielectric layer 82 is preferably selected from dielectric materials having dielectric constant (k value) larger than 4. For instance, the high-k dielectric layer 82 may be selected from hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate (SrBi₂Ta₂O₉, SBT), lead zirconate titanate (PbZrₓTi₁₋ₓO₃, PZT), barium strontium titanate (BaₓSr₁₋ₓTiO₃, BST) or a combination thereof.

In this embodiment, the work function metal layer 84 is formed for tuning the work function of the metal gate in accordance with the conductivity of the device. For an NMOS transistor, the work function metal layer 48 having a work function ranging between 3.9 eV and 4.3 eV may include titanium aluminide (TiAl), zirconium aluminide (ZrAl), tungsten aluminide (WAl), tantalum aluminide (TaAl), hafnium aluminide (HfAl), or titanium aluminum carbide (TiAlC), but it is not limited thereto. For a PMOS transistor, the work function metal layer 84 having a work function ranging between 4.8 eV and 5.2 eV may include titanium nitride (TiN), tantalum nitride (TaN), tantalum carbide (TaC), but it is not limited thereto. An optional barrier layer (not shown) could be formed between the work function metal layer 84 and the low resistance metal layer 86, in which the material of the barrier layer may include titanium (Ti), titanium nitride (TiN), tantalum (Ta) or tantalum nitride (TaN). Furthermore, the material of the low-resistance metal layer 86 may include copper (Cu), aluminum (Al), titanium aluminum (TiAl), cobalt tungsten phosphide (CoWP) or any combination thereof.

Next, part of the high-k dielectric layer 82, part of the work function metal layer 84, and part of the low resistance metal layer 86 are removed to form recesses (not shown), and a hard mask 92 is formed into each of the recesses so that the top surfaces of the hard masks 92 and the ILD layer 74 are coplanar. Preferably the hard masks 92 could include SiO₂, SiN, SiON, SiCN, or combination thereof.

Next, a photo-etching process is conducted by using a patterned mask (not shown) as mask to remove part of the ILD layer 74 adjacent to the metal gates 88 for forming contact holes (not shown) exposing the source/drain regions 72 underneath. Next, conductive materials including a barrier layer selected from the group consisting of titanium (Ti), titanium nitride (TiN), tantalum (Ta), and tantalum nitride (TaN) and a metal layer selected from the group consisting of tungsten (W), copper (Cu), aluminum (Al), titanium aluminide (TiAl), and cobalt tungsten phosphide (CoWP) are deposited into the contact holes, and a planarizing process such as CMP is conducted to remove part of aforementioned barrier layer and low resistance metal layer for forming contact plugs (not shown) electrically connecting the source/drain region. This completes the fabrication of a semiconductor device according to an embodiment of the present invention.

Referring again to FIGS. 10-11, FIGS. 10-11 further illustrate structural views of a semiconductor device integrating a HV device, a MV device, a I/O device, a core device, and a OTP capacitor according to an embodiment of the present invention. As shown in FIGS. 10-11, the semiconductor device includes a HV device disposed on the HV region 14, a MV device disposed on the MV region 16, a I/O device disposed on the I/O region 16, a core device disposed on the core region 20, and a OTP capacitor disposed on the OTP capacitor region 22. Preferably, the OTP capacitor includes at least a fin-shaped structure 26 on the substrate 12, a doped region 50 disposed in the fin-shaped structure 26, at least an insulating layer such as the interfacial layer 78 and/or high-k dielectric layer 82 on the fin-shaped structure 26, and metal such as the work function metal layer 84 and low resistance metal layer 86 on the high-k dielectric layer 82, in which the fin-shaped structure 26 having heavy doped region 50 preferably serves as a bottom electrode for the OTP capacitor, dielectric material such as the interfacial layer 78 and/or high-k dielectric layer 82 serves as a capacitor dielectric layer for the OTP capacitor, and the work function metal layer 84 and the low resistance metal layer 86 together serve as a top electrode for the OTP capacitor.

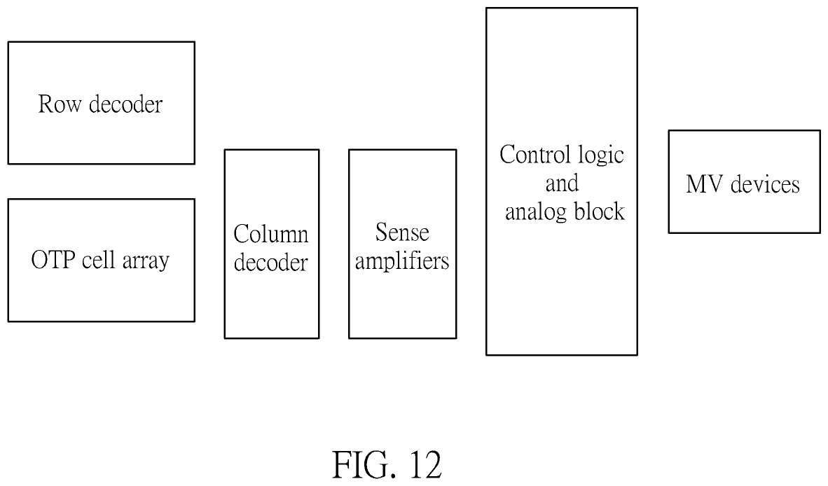

Referring to FIG. 12, FIG. 12 illustrates an overall layout of the semiconductor device according to an embodiment of the present invention. As shown in FIG. 12, the semiconductor device includes an OTP cell array, a row decoder, a column decoder, sense amplifiers, a control logic and analog block, and MV devices. Preferably, the OTP cell array includes OTP capacitors on the OTP capacitor region 22 as disclosed in the aforementioned embodiment and row and column decoders are disposed around the OTP cell array. Moreover, a control logic and analog block is disposed between the OTP cell array and the MV devices, in which the MV devices disposed immediately adjacent to the control logic and analog block preferably include circuit devices used for performing read and write operations on the OTP capacitors within the OTP cell array.

Overall, the present invention discloses an approach of integrating HV device, MV device, I/O device, core device, and OTP capacitor. Preferably, the HV devices and MV devices are fabricated according to planar MOS transistor fabrication processes while the I/O devices, core devices, and OTP capacitors are fabricated according to non-planar or more specifically FinFET fabrication processes. To enable better compatibility between the MV devices and surrounding devices, the present invention conducts an extra photo-etching process before the RMG process to pattern the gate dielectric layer 40 of the MV device so that the gate dielectric layer 40 is shaped into a reverse T-shape. Moreover, to enhance read and write ability of the OTP capacitor, it would also be desirable to remove the gate dielectric layers 52 on the core region and OTP capacitor region after removing the polysilicon gate material layers 56 during RMG process, and then form an interfacial layer 78 made of silicon oxide on the substrate 12 surface of the core region 20 and OTP capacitor region 22 afterwards. Even though the interfacial layer 78 on the core region 20 and OTP capacitor region 22 and the gate dielectric layer 52 on the I/O region 18 are both made of silicon oxide, the thickness of the interfacial layer 78 is slightly than the thickness of the gate dielectric layer 52. Through the above approach, it would be desirable to achieve much better compatibility among devices disposed on the HV region, MV region, I/O region, core region, and OTP capacitor region.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a substrate having a medium-voltage (MV) region and an one time programmable (OTP) capacitor region;
a MV device on the MV region; and
an OTP capacitor on the OTP capacitor region.

2. The semiconductor device of claim 1, wherein the MV device comprises:
a first gate dielectric layer on the substrate;
a first gate electrode on the first gate dielectric layer;
a spacer adjacent to the first gate electrode; and
a shallow trench isolation (STI) adjacent to two sides of the first gate electrode.

3. The semiconductor device of claim 2, wherein the first gate dielectric layer comprises a reverse T-shape.

4. The semiconductor device of claim 2, wherein the first gate dielectric layer comprises:
a bottom portion on the STI and the substrate; and
a top portion on the bottom portion.

5. The semiconductor device of claim 4, wherein a width of the top portion is less than a width of the bottom portion.

6. The semiconductor device of claim 4, wherein sidewalls of the top portion and the spacer are aligned.

7. The semiconductor device of claim 2, wherein the OTP capacitor comprises:
a fin-shaped structure on the substrate;
a doped region in the fin-shaped structure;
an interfacial layer on the doped region; and
a top electrode on the interfacial layer.

8. The semiconductor device of claim 7, wherein top surface of the first gate dielectric layer and the doped region are coplanar.

9. A semiconductor device, comprising:
a substrate having a medium-voltage (MV) region, an one time programmable (OTP) capacitor region, and a core region;
a MV device on the MV region;
an OTP capacitor on the OTP capacitor region; and
a metal-oxide-semiconductor (MOS) transistor on the core region.

10. The semiconductor device of claim 9, wherein the MV device comprises:
a first gate dielectric layer on the substrate;
a first gate electrode on the first gate dielectric layer;
a spacer adjacent to the first gate electrode; and
a shallow trench isolation (STI) adjacent to two sides of the first gate electrode.

11. The semiconductor device of claim 10, wherein the first gate dielectric layer comprises a reverse T-shape.

12. The semiconductor device of claim 10, wherein the first gate dielectric layer comprises:
a bottom portion on the STI and the substrate; and
a top portion on the bottom portion.

13. The semiconductor device of claim 12, wherein a width of the top portion is less than a width of the bottom portion.

14. The semiconductor device of claim 12, wherein sidewalls of the top portion and the spacer are aligned.

15. The semiconductor device of claim 10, wherein the OTP capacitor comprises:
a first fin-shaped structure on the substrate;
a doped region in the first fin-shaped structure;
a first interfacial layer on the doped region; and
a top electrode on the first interfacial layer.

16. The semiconductor device of claim 10, wherein top surface of the first gate dielectric layer and the doped region are coplanar.

17. The semiconductor device of claim 15, wherein the MOS transistor comprises:
a second fin-shaped structure on the substrate;
a second interfacial layer on the second fin-shaped structure;
a second gate electrode on the second interfacial layer; and
a source/drain region adjacent to two sides of the second gate electrode.
